(19) United States
(12) Patent Application Publication
(10) Pub. No.: US 2026/0322348 A1
(43) Pub. Date: Oct. 15, 2026

(54) COMPOSITE SUBSTRATE FOR SURFACE ACOUSTIC WAVE DEVICES

(71) Applicant: SHIN-ETSU CHEMICAL CO., LTD., Tokyo (JP)

(72) Inventors: Masayuki TANNO, Annaka-shi (JP); Shoji AKIYAMA, Annaka-shi (JP); Hirokazu SASAKI, Takasaki-shi (JP)

(73) Assignee: SHIN-ETSU CHEMICAL CO., LTD., Tokyo (JP)

(21) Appl. No.: 19/481,383

(22) PCT Filed: Apr. 1, 2024
(86) PCT No.: PCT/JP2024/013466

§ 371 Date: Nov. 4, 2025

(30) Foreign Application Priority Data
May 9, 2023 (JP) 2023-077370

(51) Int. Cl. H03H 9/02; H03H 9/64

(52) U.S. Cl. CPC H03H 9/02574; H03H 9/02559; H03H 9/6406

(57) ABSTRACT

Provided is a composite substrate for surface acoustic wave devices, the composite substrate including a piezoelectric single crystal thin film, a support substrate, and at least one intervening layer that is provided between the piezoelectric single crystal thin film and the support substrate, the intervening layer being in contact with the piezoelectric single crystal thin film, the total thickness of the intervening layer being equal to or less than twice the wavelength of the surface acoustic wave, and the attenuation of a longitudinal wave of the intervening layer as calculated by a Brillouin oscillation method at a frequency of 40 GHz to 60 GHz being 8×10⁻² (nm⁻¹·THz⁻²) or less. According to the present invention, it is possible to provide a composite substrate for surface acoustic wave devices, which has a small loss in the pass band of a filter, few spurious components, and excellent high performance and high reliability.

### TECHNICAL FIELD

The present invention relates to a composite substrate for surface acoustic wave devices, which is composed of a piezoelectric single crystal thin film and a support substrate.

### BACKGROUND ART

In mobile phones and other devices, surface acoustic wave (SAW) devices are used as frequency adjustment and selection components, with comb electrodes (IDT: Inter Digital Transducer) formed on a piezoelectric substrate to excite surface acoustic waves. Surface acoustic wave devices are required to be small, have low insertion loss, and not allow unwanted waves to pass through, and piezoelectric materials such as lithium tantalate (LiTaO₃; LT) and lithium niobate (LiNbO₃; LN) are used for surface acoustic wave devices.

On the other hand, under the communication standards for fourth generation and later mobile phones, the piezoelectric materials used in surface acoustic wave devices need to have sufficiently small temperature-induced characteristic variations. In order to prevent unnecessary noise from spilling out between bands, filters, duplexers, and multiplexers are required to have as small an insertion loss as possible, and the shoulder characteristics of the filter need to be extremely steep, and resonators that make up the filter are required to have a high Q value (Quality Factor). In addition, filters are required to be compatible with a wide bandwidth depending on the band used.

Regarding materials used in such surface acoustic wave devices, composite substrates made of piezoelectric materials and other materials are being considered. For example, PTL 1 discloses an acoustic wave device having a piezoelectric film, the acoustic wave device including a support substrate, a high sound velocity film formed on the support substrate and having a propagating bulk wave sound velocity higher than the acoustic wave velocity propagating through the piezoelectric film, a low sound velocity film laminated on the high sound velocity film and having a propagating bulk wave sound velocity lower than the bulk wave sound velocity propagating through the piezoelectric film, the piezoelectric film laminated on the low sound velocity film, and an IDT electrode formed on one side of the piezoelectric film.

Furthermore, PTL 2 discloses an acoustic wave device including a support substrate, a medium layer laminated on the support substrate, a piezoelectric body laminated on the medium layer and through which bulk waves propagate, and an IDT electrode formed on one side of the piezoelectric body, the medium layer including a low velocity medium in which the propagation velocity of a bulk wave, which is the same as the bulk wave that is a main component of the acoustic wave, is lower than the sound velocity of the acoustic waves propagating through the piezoelectric body, and a high velocity medium in which the propagation velocity of a bulk wave, which is the same as the bulk wave that is the main component of the acoustic wave, is higher than the sound velocity of the acoustic waves propagating through the piezoelectric body, the medium layer being formed such that, when the sound velocity of a main vibration mode in the case of forming the medium layer in the high velocity medium is VH and the sound velocity of a main vibration mode in the case of forming the medium layer in the low velocity medium is VL, the sound velocity of the main vibration mode in the acoustic wave device in which the medium layer is formed satisfies VL<sound velocity of the main vibration mode <VH, and the medium layer having a thickness of 1λ or more, where λ is the period of the IDT.

### CITATION LIST

### Patent Literature

PTL 1:JP 5713025 B
PTL 2:JP 5861789 B

### SUMMARY OF INVENTION

### Technical Problem

However, when a surface acoustic wave filter is made using the composite substrate of PTL 1 or PTL 2, the energy of the acoustic wave leaks from the piezoelectric body into and remains in the low velocity medium, causing a problem that noise called spurious or ripple occurs within the pass band of the surface acoustic wave filter or at higher frequencies. The noise is caused by wave reflection at an interface between a piezoelectric crystal film and the support substrate, or by trapping of acoustic waves in an intervening layer between the piezoelectric crystal film and the support substrate, and is undesirable because it deteriorates the frequency characteristics of the surface acoustic wave filter and causes an increase in loss in the pass band of the filter.

The present invention has been made in view of the above circumstances, and an object thereof is to provide a composite substrate for surface acoustic wave devices, which has a small loss in the pass band of a filter, few spurious components, and excellent high performance and high reliability.

### Solution to Problem

As a result of intensive research, the inventors of the present invention have found that by providing a piezoelectric single crystal thin film, a support substrate, and at least one intervening layer between the piezoelectric single crystal thin film and the support substrate, and by specifying the total thickness of the intervening layer and the attenuation of longitudinal waves, the loss in the pass band of the filter can be reduced and high reliability can be obtained, and have completed the present invention. The gist of the present invention is as follows.

[1]A composite substrate for surface acoustic wave devices, the composite substrate including a piezoelectric single crystal thin film, a support substrate, and at least one intervening layer that is provided between the piezoelectric single crystal thin film and the support substrate, the intervening layer being in contact with the piezoelectric single crystal thin film, the intervening layer having a total thickness equal to or less than twice a wavelength of the surface acoustic wave, and an attenuation of a longitudinal wave of the intervening layer as calculated by a Brillouin oscillation method at a frequency of 40 GHz to 60 GHz being 8×10⁻² (nm⁻¹·THz⁻²) or less.

[2] The composite substrate for surface acoustic wave devices according to [1], in which transverse waves of the intervening layer has a sound velocity higher than that of slow transverse waves of the piezoelectric single crystal thin film.

[3] The composite substrate for surface acoustic wave devices according to [1] or [2], in which the piezoelectric single crystal thin film contains 120 ppm or less of iron, and the piezoelectric single crystal thin film has a volume resistivity of 2×10¹¹ Ω·cm or less.

[4] The composite substrate for surface acoustic wave devices according to any one of [1] to [3], in which the intervening layer is either SiOx (1.8<x<2.05) or SiOyNz (0.02<z/(y+z)<0.1).

[5] The composite substrate for surface acoustic wave devices according to any one of [1] to [4], in which the piezoelectric single crystal thin film has a main component of lithium tantalate or lithium niobate.

[6] The composite substrate for surface acoustic wave devices according to any one of [1] to [5], in which the support substrate is any one of a silicon substrate, a sapphire substrate, an alumina substrate, a silicon carbide substrate, an aluminum nitride substrate, a silicon nitride substrate, and a quartz substrate.

[7] The composite substrate for surface acoustic wave devices according to any one of [1] to [5], in which the support substrate is made of a single crystal Si and a polysilicon layer formed on the single crystal Si.

[8] The composite substrate for surface acoustic wave devices according to any one of [1] to [7], in which Li ions in the intervening layer has a content of 1×10¹⁷ atom/cm³ or less.

### Advantageous Effects of Invention

According to the present invention, it is possible to provide a composite substrate for surface acoustic wave devices, which has a small loss in the pass band of a filter and high reliability.

### BRIEF DESCRIPTION OF DRAWINGS

FIG. 1 is a diagram showing an example of a spectrum of Brillouin oscillations of a SiO_{1.7} thin film.

FIG. 2 is a diagram showing a waveform obtained by Fourier transforming only reflected light of ultrasonic waves (longitudinal waves) in a thin film.

FIG. 3 is a diagram showing a relationship of dependency between an LSAW sound velocity of a thin film and a value of the thin film thickness normalized by the wavelength of the ultrasonic wave (thin film thickness/wavelength), and a calculation result of the sound velocity of an acoustic wave obtained by a finite element method.

FIG. 4 is a diagram showing an example of a calculation result of the displacement distribution of a wave in which the energy of an acoustic wave is concentrated on a surface layer of a thin film of a SiO_{1.7} thin film/(111)Si substrate structure.

FIG. 5 is a diagram showing an example of a cross-sectional TEM observation photograph of a composite substrate produced in Example 1.

FIG. 6 is a diagram showing a composite substrate having an A1 microelectrode formed on the surface.

FIG. 7 is a diagram showing a resonant waveform (input impedance (Zin) and Q value) of SAW obtained in Example 1.

FIG. 8 is a diagram showing a resonant waveform (input impedance (Zin) and Q value) of SAW obtained in Example 2.

FIG. 9 is a diagram showing a resonant waveform (input impedance (Zin) and Q value) of SAW obtained in Comparative Example 1.

FIG. 10 is a diagram showing a resonant waveform (input impedance (Zin) and Q value) of SAW obtained in Comparative Example 2.

### DESCRIPTION OF EMBODIMENTS

Hereinafter, a composite substrate for surface acoustic wave devices of the present invention will be described in detail; however, the present invention is not limited to the embodiment. In addition, a numerical range defined by using the expression “X to Y” includes numerical values at both ends (upper limit and lower limit) of “X to Y”.

### [Composite Substrate for Surface Acoustic Wave Devices]

The composite substrate for surface acoustic wave devices of the present invention is a composite substrate including a piezoelectric single crystal thin film, a support substrate, and at least one intervening layer that is provided between the piezoelectric single crystal thin film and the support substrate, the intervening layer being in contact with the piezoelectric single crystal thin film, the total thickness of the intervening layer being equal to or less than twice the wavelength of the surface acoustic wave, and the attenuation of a longitudinal wave of the intervening layer as calculated by a Brillouin oscillation method at a frequency of 40 GHz to 60 GHz being 8×10⁻² (nm⁻¹·THz⁻²) or less.

### (Piezoelectric Single Crystal Thin Film)

The piezoelectric single crystal thin film in the composite substrate for surface acoustic wave devices in one embodiment of the present invention is not particularly limited as long as it can be used as a piezoelectric film; however, it is preferable that the main component is lithium tantalate (LiTaO₃:LT) or lithium niobate (LiNbO₃:LN). By using the above-mentioned components as the main components of the piezoelectric single crystal thin film, an acoustic wave device with large electromechanical coupling can be obtained.

In the present invention, that the main component of the piezoelectric single crystal thin film is lithium tantalate or lithium niobate means that 50% by mass or more of the components constituting the piezoelectric single crystal thin film are lithium tantalate or lithium niobate. In addition, the piezoelectric single crystal thin film may contain iron, magnesium, etc., as components other than lithium tantalate and lithium niobate.

Further, it is preferable that the piezoelectric single crystal thin film contains 120 ppm or less of iron. By containing a small amount of iron in the piezoelectric single crystal thin film, an electric field at which the polarization of the piezoelectric single crystal thin film is destroyed, that is, a coercive electric field, increases, making it difficult for the polarization to be destroyed. From the above viewpoint, the content of iron is more preferably 10 ppm or more and 120 ppm or less, and even more preferably 50 ppm or more and 100 ppm or less.

In addition, it is preferable that the initial volume resistivity of the piezoelectric single crystal thin film is 2×10¹¹ Ω·cm or less. By having the initial volume resistivity of the piezoelectric single crystal thin film of 2×10¹¹ Ω·cm or less, the constant temperature resistance of the composite substrate for surface acoustic wave devices of the present invention can be improved. The initial volume resistivity of the piezoelectric single crystal thin film is more preferably 2×10¹⁰ Ω·cm or more and 2×10¹¹ Ω·cm or less, and even more preferably 2×10¹⁰ Ω·cm or more and 1×10¹¹ Ω·cm or less.

### (Support Substrate)

In one embodiment of the present invention, the support substrate in the composite substrate for surface acoustic wave devices can be any one of a silicon substrate, a sapphire substrate, an alumina substrate, a silicon carbide substrate, an aluminum nitride substrate, a silicon nitride substrate, and a quartz substrate.

A surface acoustic wave resonator produced using a composite substrate for surface acoustic wave devices using the above substrate as the support substrate can provide a surface acoustic wave device with a high Q value, further suppression of out-of-band spurious, and excellent temperature characteristics.

Further, the support substrate may be made of a single crystal Si and a polysilicon layer formed on the single crystal Si.

By appropriately adjusting the thickness of the polysilicon layer of the support substrate, it is possible to further suppress out-of-band spurious.

The thickness of the polysilicon layer is preferably 0.2 μm or more and 2 μm or less, more preferably 0.5 μm or more and 1.9 μm or less, and still more preferably 0.5 μm or more and 1.2 μm or less.

### (Intervening Layer)

The composite substrate for surface acoustic wave devices of the present invention includes an intervening layer between the piezoelectric single crystal thin film and the support substrate, and the intervening layer is provided in contact with the piezoelectric single crystal thin film. In one embodiment of the present invention, the intervening layer in the surface acoustic wave device composite substrate is either SiOx (1.8<x<2.05) or SiOyNz (0.02<z/(y+z)<0.1).

Furthermore, the composite substrate for surface acoustic wave devices of the present invention includes at least one intervening layer. The intervening layer may be one layer or two or more layers, and when there are two or more layers, each layer may be made of the same material or different materials.

The content of Li ions in the intervening layer is preferably 1×10¹⁷ atom/cm³ or less. Li ions mainly diffuse from the piezoelectric single crystal thin film to the intervening layer; and by setting the Li ion content in the intervening layer to 1×10¹⁷ atom/cm³ or less, softening of the intervening layer can be prevented and in-band and out-of-band spurious can be suppressed.

Furthermore, the thickness of the intervening layer is the thickness of the intervening layer when there is one layer of the intervening layer, and when there are two or more layers of the intervening layer, the total thickness is equal to or less than twice the wavelength of the surface acoustic wave of the intervening layer. When the thickness of the intervening layer exceeds twice the wavelength of the surface acoustic wave of the intervening layer, the acoustic wave is easily trapped in the intervening layer, resulting in a problem of increased out-of-band spurious. The total thickness of the intervening layer is preferably equal to or less than twice the wavelength of the surface acoustic wave, and more preferably equal to or less than the wavelength of the surface acoustic wave.

Furthermore, the attenuation of the longitudinal waves in the intervening layer calculated at a frequency of 40 GHz to 60 GHz by a Brillouin oscillation method is 8×10⁻² (nm⁻¹·THz⁻²) or less.

When the acoustic attenuation of the longitudinal waves in the intervening layer is large, the acoustic waves are easily trapped in the intervening layer. In this case, the surface acoustic wave resonator made of the composite substrate for surface acoustic wave devices of the present invention has a problem of large out-of-band spurious. By setting the attenuation of the longitudinal waves of the intervening layer to 8×10⁻² (nm⁻¹·THz⁻²) or less, the Q value of the surface acoustic wave resonator is high, and out-of-band spurious can be further suppressed. The attenuation of the longitudinal waves of the intervening layer is preferably 2×10⁻² (nm¹·THz⁻²) or less, and more preferably 0.5×10⁻² (nm⁻¹·THz⁻²) or less.

In addition, the sound velocity of the transverse waves of the intervening layer is preferably higher than the sound velocity of the slow transverse waves of the piezoelectric single crystal thin film. By making the velocity of the transverse waves (bulk waves) of the intervening layer higher than that of the slow transverse waves (bulk waves) of the piezoelectric single crystal thin film, the loss in the pass band of the surface acoustic wave filter obtained using the composite substrate for surface acoustic wave devices can be improved. When the velocity of the transverse waves in the intervening layer is lower than the slow transverse waves in the piezoelectric single crystal thin film, there is a concern that the acoustic waves may be easily trapped in the intervening layer. Since the piezoelectric single crystal thin film is an anisotropic material, there are two types of transverse waves in the piezoelectric single crystal thin film, i.e., fast transverse waves and slow transverse waves.

For example, in LiTaO₃ as an example of the piezoelectric single crystal thin film, the slow transverse wave of 46° rotated Y-cut LiTaO₃ is 3330 m/s. In addition, in SiO_{1.85} or SiO_{1.94}N_{0.06} as an example of the intervening layer, the sound velocity of the transverse wave of SiO_{1.85} or SiO_{1.94}N_{0.06} is high, at 3850 m/s and 3750 m/s, respectively. The sound velocity of the transverse waves in SiO_{1.85} or SiO_{1.94}N_{0.06} will be described in detail later; however, it can be determined from a measured transverse wave sound velocity of the LSAW of the piezoelectric single crystal thin film using a linear convergent beam ultrasonic microscope and analysis using the finite element method, as described in, for example, Tatsuya Omoril, Kensuke Sakamoto, Satoshi Suzuki, Jun-ichi Kushibiki, Satoru Matsuda, and Ken-ya Hashimoto, “Characterization of Elastic Properties of SiO₂ Thin Films by Ultrasonic Microscopy”.

By using SiO_{1.85} or SiO_{1.94}N_{0.06} for the intervening layer and LiTaO₃ for the piezoelectric single crystal thin film, the sound velocity of the transverse waves in the intervening layer can be made higher than the sound velocity of the slow transverse waves in the piezoelectric single crystal thin film.

In addition, when obtaining the attenuation of the longitudinal waves of the intervening layer calculated at a frequency of 40 GHz to 60 GHz by the Brillouin oscillation method, the attenuation was 1.2×10⁻² (nm⁻¹·THz⁻²) for SiO_{1.85} and 0.1×10⁻² (nm⁻¹·THz⁻²) for SiO_{1.94}N_{0.06}, and the attenuation of the longitudinal waves can be set to 8×10⁻² (nm⁻¹·THz⁻²) or less.

Here, a method described in H.Ogi et.al, “Elastic constant and Brillouin oscillations in sputtered vitreous SiO₂ thin films”, PHISICAL REVIEW B 78,13204 (2008) can be used as the Brillouin oscillation method. FIG. 1 shows an example of the spectrum of Brillouin oscillations of a SiO_{1.7} thin film having the same composition and production method as the intervening layer, when the composition of the intervening layer is SiO_{1.7.}

The SiO_{1.7} thin film (hereinafter, simply referred to as “thin film”) used in the measurement of FIG. 1 was formed on a Si substrate with a thickness of 1055 nm (the thickness is d) of SiO_{1.7} thin film of the same composition and production method as the intervening layer, and an Al film of 10 nm was further formed on the SiO_{1.7} thin film. The production method of the thin film is not particularly limited, and may be, for example, a CVD method. Ultra-high frequency ultrasonic waves are generated by irradiating a structure consisting of the Al film, SiO_{1.7} thin film, and Si substrate with extremely short pulse light. Further, delayed pulse light with a reference wavelength (λ) of 400 nm is irradiated. The longitudinal wave sound velocity of the thin film can be obtained by detecting the light diffracted by the ultrasonic waves in the thin film.

At this time, the density of the thin film and the refractive index at 400 nm are obtained in advance. The refractive index (n) of the thin film at 400 nm was 1.728 using a prism coupler method.

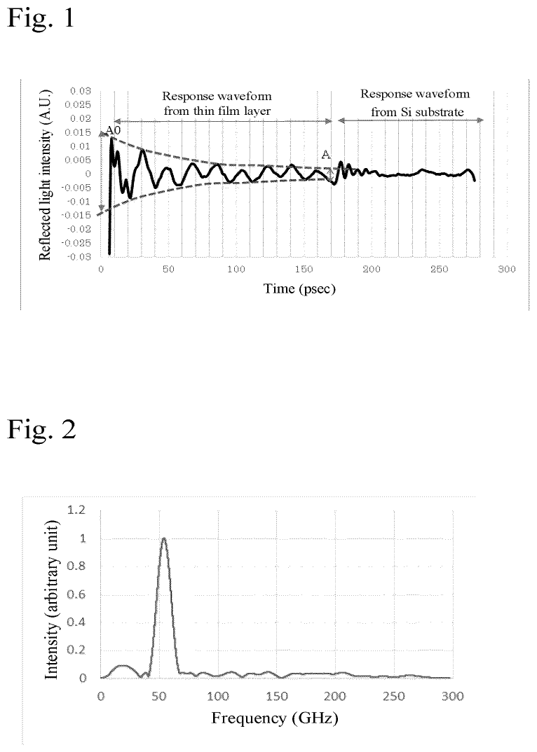

The density (p) of the thin film determined by XPS (X-ray photoelectron spectroscopy) was 2300 kg/m³. The first half of the Brillouin spectrum shown in FIG. 1 shows the reflected light intensity due to diffraction by ultrasonic waves (longitudinal waves) in the thin film. By Fourier transforming only the reflected light of ultrasonic waves (longitudinal waves) in the thin film, the frequency of the ultrasonic waves (longitudinal waves) in the thin film shown in FIG. 2 can be obtained. From FIG. 2, the frequency (f) of the ultrasonic waves (longitudinal waves) in the thin film can be calculated to be 54.5 GHz.

At this time, the sound velocity vl of the ultrasonic waves (longitudinal waves) in the thin film can be calculated using the following Formula (1).

vl=f×λ/(2×n) Formula (1)

The sound velocity of the ultrasonic waves (longitudinal waves) in the thin film shown in FIG. 2, calculated using Formula (1), was 6325 m/s. The elastic constant C11 of the thin film can be calculated using vl=\sqrt{C11/ρ}, and the elastic constant C11 of the thin film was 92 GPa.

Next, description will be made to how to determine the sound velocity of transverse waves in a SiO_{1.7} film using the linear convergent beam ultrasonic microscope and the finite element method.

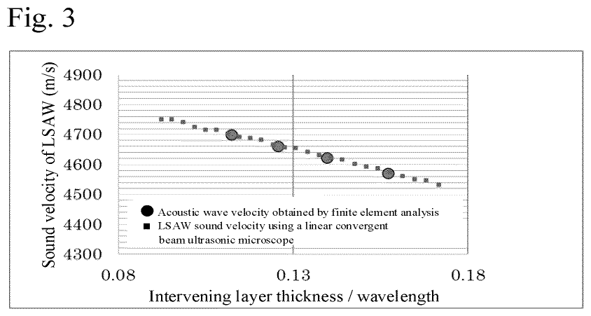

First, for example, by using a linear convergent beam ultrasonic microscope as described in the above-mentioned Tatsuya Omoril, Kensuke Sakamoto, Satoshi Suzuki, Jun-ichi Kushibiki, Satoru Matsuda, and Ken-ya Hashimoto, “Characterization of Elastic Properties of SiO₂ Thin Films by Ultrasonic Microscopy”, the LSAW sound velocity of the thin film was measured by varying the frequency from 160 MHz to 275 MHz to obtain the dependency of the value of the thin film thickness normalized by the wavelength of the ultrasonic wave (thin film thickness/wavelength). The relationship diagram is shown in FIG. 3.

The LSAW sound velocity (vertical axis) measured by the linear convergent beam ultrasonic microscope in FIG. 3 was obtained by forming a SiO_{1.7} thin film having a thickness of 2830 nm with the same composition and production method as the intervening layer on a substrate with a Si (111) orientation, and propagating the LSAW to the surface layer of the SiO_{1.7} thin film/Si substrate structure through pure water as a couplant such that the linear convergent beam of the linear convergent beam ultrasonic microscope was shifted 45 degrees clockwise from the (110) direction in the Si substrate plane when viewed from the thin film side.

On the other hand, using the two-dimensional finite element method, a ZnO film and an Al electrode, sufficiently thin compared to the electrode period, were placed on the surface layer of the thin film of the SiO_{1.7} thin film/(111) Si substrate structure, and an acoustic wave was excited in a direction shifted 45 degrees clockwise from the <110> direction of the Si of the thin film-attached Si substrate, and the wavelength determined by the electrode period was varied on the finite element method calculation model to calculate the relationship between the acoustic wave velocity of the SiO_{1.7} thin film/(111) Si substrate structure and the intervening layer normalized by the wavelength. At this time, since the elastic constant C12 of the SiO_{1.7} thin film is an unknown quantity, a provisional value was input for C12, and C12 was determined so as to match the measurement result of the LSAW sound velocity using the linear convergent beam ultrasonic microscope in FIG. 3. For the other constants (C11, ρ), the values mentioned above were used to calculate.

The value of C12 obtained above was 20 GPa. Furthermore, the calculation results of the acoustic velocity of acoustic waves using the finite element method when the elastic constant C12 of the SiO_{1.7} thin film is 20 GPa are shown in FIG. 3.

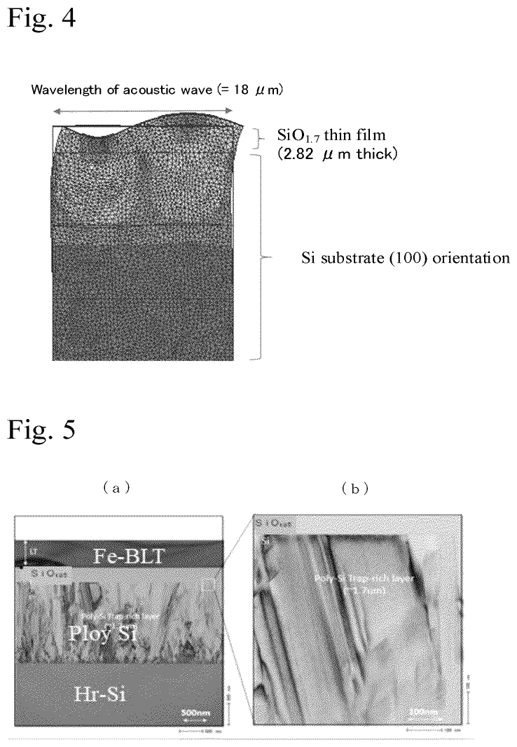

As an example, in a calculation model using the finite element method when the acoustic wave wavelength is 18 μm, the calculation result of the displacement distribution of a wave in which the energy of the acoustic wave is concentrated on the surface layer of the thin film of the SiO_{1.7} thin film/(111)Si substrate structure is shown in FIG. 4.

From the above study, the transverse wave sound velocity Vs(={square root over ((C11-C12)/ρ))}) of the SiO_{1.7} thin film alone was calculated, and as a result, Vs=3960 m/s was obtained. In the calculation model using the finite element method of the present application, the elastic constants of the Si substrate, ZnO film, and Al film were taken from the values given in the Surface Acoustic Wave Data Book (edited by the Electronic Industries Association of Japan (zaidanhoujin nihon denshi kougyou kougyoukai)), (p. 66 (ZnO), p. 165 (Si), p. 172 (Al)).

In addition, in the study of the present application, as a unique attempt, the present application focused on the fact that the reflected light intensity due to diffraction by ultrasonic waves (longitudinal waves) in the thin film layer, which is the first half of the Brillouin spectrum shown in FIG. 1, attenuates exponentially over time. That is, in the envelope of the reflected light intensity shown by the dotted line in FIG. 1, in a case where the amplitude intensity at 0 psec is A0 and the amplitude intensity at the time when the ultrasonic waves reach Si is A, the attenuation constant (β) of ultrasonic waves (longitudinal waves) in the thin film is described by Formula (2).

A=A0 exp(−β·f²·d) Formula (2)

In the case of FIG. 2, A0 was 0.03 and A was 0.004. From the above, the attenuation constant β is calculated from Formula (3).

β=−1/(f²·d)·In(A/A0) Formula (3)

In the case of FIG. 2, β was 10.8×10⁻² (nm⁻¹·THz²).

For the various intervening layers described above, the attenuation of longitudinal waves was calculated at frequencies of 40 GHz to 60 GHz using the Brillouin oscillation method in the same manner as above.

When the acoustic attenuation of the longitudinal waves in the intervening layer is large, the acoustic waves are easily trapped in the intervening layer. In this case, it was confirmed that the surface acoustic wave resonator made of the composite substrate for surface acoustic wave devices has a problem of large out-of-band spurious.

On the other hand, when the intervening layer according to the present invention has a high acoustic velocity and little attenuation of longitudinal waves, the acoustic waves cannot be concentrated excessively in the intervening layer, and the wave energy can be concentrated in the piezoelectric single crystal thin film. Therefore, the surface acoustic wave resonator using the composite substrate for surface acoustic wave devices of the present invention has a high Q value, and out-of-band spurious is further suppressed, which is preferable.

### EXAMPLES

Hereinafter, the present invention will be described in more detail with reference to Examples, but the present invention is not limited thereto.

### Example 1

A polysilicon layer of 1.7 μm was formed on the surface layer of a (111) oriented high-resistance silicon substrate with a diameter of 150 nm.

Then, a melt with a composition in which the amount of lithium was reduced based on the amount of lithium contained in a lithium tantalate crystal of a congruent composition was prepared, and an iron-substituted lithium tantalate crystal was grown from the melt with the adjusted composition.

A 6-inch iron-containing 42° Y-cut lithium tantalate (LT) substrate was prepared by adjusting the amount of added iron such that the iron content in the iron-substituted lithium tantalate crystal was 95 ppm by mass. The volume resistivity of the iron-containing 42° Y-cut lithium tantalate (LT) substrate was adjusted to 2.2×10¹⁰ Ω·cm by reduction treatment.

Then, hydrogen molecular ions were implanted into the 6-inch iron-containing lithium tantalate (LT) substrate from a surface to be bonded. The dose at this time was 9×10¹⁶ atm/cm², and the acceleration voltage was 160 KeV.

Next, a 0.4 μm thick intervening layer with a composition of SiO_{1.85} was formed by CVD method on the ion-implanted surface of the 6-inch iron-containing lithium tantalate (LT) substrate into which hydrogen molecular ions had been implanted.

Then, the silicon substrate on which the polysilicon layer was formed and the iron-containing LT substrate having the 0.4 μm thick intervening layer using SiO_{1.85} were subjected to surface activation treatment by plasma treatment. Furthermore, the silicon substrate on which the polysilicon layer was formed and the iron-containing LT substrate were bonded together with the 0.4 μm thick intervening layer using SiO_{1.85} interposed therebetween to form a bonded body.

Next, the bonded body was subjected to heat treatment at 350° C. under nitrogen to prevent the introduction of crystal defects due to misalignment of the bonding interface. Then, the heat-treated bonded body was heated to 110° C., and a wedge was driven into one end of the ion-implanted portion of the iron-containing lithium tantalate (LT) substrate to separate it into the iron-containing lithium tantalate (LT) piezoelectric single crystal thin film layer bonded to the silicon substrate and the remaining iron-containing lithium tantalate (LT) substrate.

The thickness of the iron-containing lithium tantalate (LT) piezoelectric single crystal thin film layer bonded to the silicon substrate after separation was measured with a spectrophotometer and found to be 0.52 μm. Next, the composite substrate consisting of the iron-containing lithium tantalate (LT) piezoelectric single crystal thin film layer bonded to the silicon substrate was heated at 500° C. for 6 hours.

Furthermore, the surface layer of the iron-containing lithium tantalate (LT) piezoelectric single crystal thin film of the composite substrate was polished by 20 nm, and the thickness of the iron-containing lithium tantalate (LT) piezoelectric single crystal thin film layer bonded to the silicon substrate was measured with a spectrophotometer, and found to be 0.5 μm.

FIG. 5 is a diagram showing an example of a cross-sectional TEM observation photograph of the composite substrate of Example 1 produced by the above method, and FIG. 5 (b) is a photograph with a part of FIG. 5 (a) further enlarged.

The amount of Li in the intervening layer (SiO_{1.85} layer) of the composite substrate produced by the above method was measured by secondary ion mass spectrometry (SIMS), and the maximum amount of Li in the SiO_{1.85} layer was 2×10¹⁶ atom/cm³. The composition ratio of the intervening layer (SiO_{1.85} layer) was determined by X-ray photoelectron spectroscopy (XPS).

Furthermore, the density of the intervening layer (SiO_{1.85} layer) was determined by XPS (X-ray photoelectron spectroscopy) and was found to be 2240 g/cm³. The longitudinal wave sound velocity and attenuation of the intervening layer (SiO_{1.85} layer) were determined by the Brillouin oscillation method. As a result, the longitudinal wave sound velocity of the intervening layer (SiO_{1.85} layer) was 6200 m/s, and the sound attenuation rate was 1.2×10⁻³ (nm⁻¹·THz⁻²) at 55 GHz.

The transverse wave sound velocity of the intervening layer (SiO_{1.85} layer) alone was determined by combining the linear convergent beam ultrasonic microscope and finite element analysis, and was found to be 3850 m/s.

Next, an Al film was sputtered to a thickness of 0.14 μm onto the surface of the composite substrate obtained above, a resist was applied, and then a resist pattern with a line width of approximately 0.5 μm was formed by i-line exposure. The Al was then etched by dry etching to form a first layer of a one-port SAW resonator. At this time, the wavelength of the surface acoustic wave was 2 μm, and the thickness of the intervening layer (SiO_{1.85} layer) was 0.2 wavelengths.

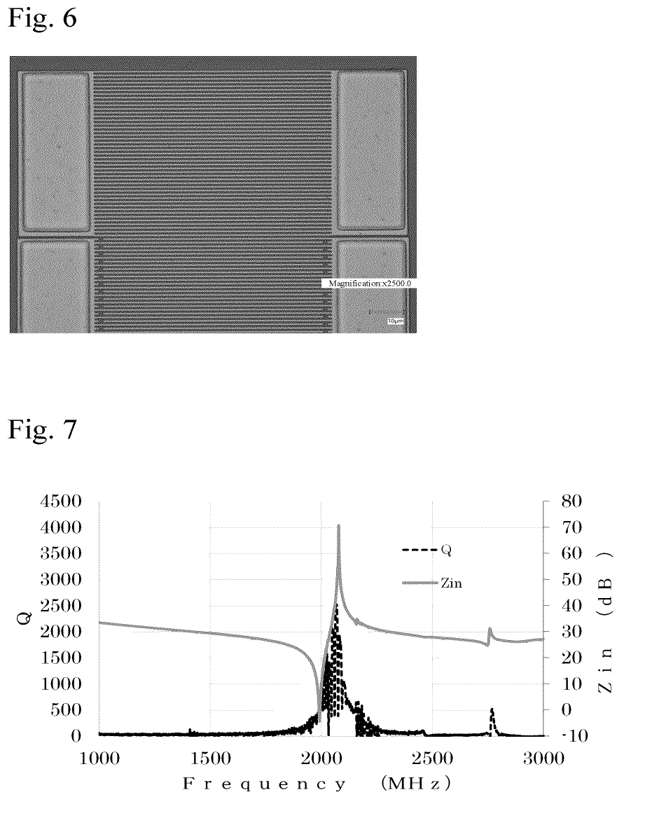

Furthermore, a second layer of pads having an Al film thickness of 0.6 μm was formed on the composite substrate by a lift-off method. FIG. 6 shows a composite substrate having an Al microelectrode formed on the surface.

Next, the electrical characteristics of the one-port SAW resonator on the iron-containing lithium tantalate (LT) piezoelectric single crystal thin film substrate bonded to the silicon substrate created above were measured using a network analyzer. The resulting resonant waveform (input impedance (Zin) and Q value) of SAW is shown in FIG. 7.

Table 1 shows the resonance frequency (fr), anti-resonance frequency (fa), electromechanical coupling coefficient (k²), maximum Q value (Qmax), input impedance amplitude (ΔZ), fractional bandwidth (fractional bandwidth=(anti-resonance frequency −resonance frequency)/resonance frequency), and spurious intensity of 2400 to 2800 MHz of the SAW resonator.

TABLE 1

| Resonance | | Electromechanical | | Amplitude of | | Maximum spurious |
|---|---|---|---|---|---|---|
| frequency | Anti-resonance | coupling coefficient | Maximum | input impedance | Fractional | intensity at |
| (fr) | frequency (fa) | (k²) | value of Q | (ΔZ) | bandwidth | 2400 to 2800 MHz |
| MHz | MHz | % | (Qmax) | (db) | % | (db) |
| 1992.9 | 2079.1 | 9.8 | 2522.4 | 75.0 | 4.3 | 6.4 |

Next, the iron-containing lithium tantalate (LT) piezoelectric single crystal thin film substrate bonded to the silicon substrate with the one-port SAW resonator pattern created above was placed on a hot plate heated to 350° C. for 10 minutes, then placed on a cooling plate at room temperature to cool, and the electrical characteristics of the one-port SAW resonator were measured again using the network analyzer. The resulting characteristics were the same as those in Table 1. Furthermore, the 350° C. hot plate heating, cooling and measurement were repeated for a cumulative time of 4 hours in total for 350° C. hot plate heating, and the electrical characteristics of the one-port SAW resonator after each cumulative time of heating were not different from those in Table 1.

### Example 2

A composite substrate consisting of an iron-containing lithium tantalate (LT) piezoelectric single crystal thin film bonded to a silicon substrate was prepared in the same manner as in Example 1, except that a 0.3 μm thick intervening layer having a composition of SiO_{1.94}N_{0.06} was used instead of the 0.4 μm thick intervening layer having a composition of SiO_{1.85} used in Example 1.

The amount of Li in the intervening layer (SiO_{1.94}N_{0.06} layer) of the iron-containing lithium tantalate (LT) piezoelectric single crystal thin film substrate bonded to the silicon substrate was measured by secondary ion mass spectrometry (SIMS), and the amount of Li in the SiO_{1.94}N_{0.06} layer was 1×10¹⁴ atom/cm³ or less. The composition ratio of the intervening layer (SiO_{1.94}N_{0.06} layer) was determined by X-ray photoelectron spectroscopy (XPS).

In addition, the LT layer of the composite substrate consisting of the iron-containing lithium tantalate (LT) piezoelectric single crystal thin film bonded to the silicon substrate was removed, and the density of the intervening layer (SiO_{1.94}N_{0.06} layer) was determined by X-ray reflectivity measurement (XRR). As a result, the density of the intervening layer (SiO_{1.94}N_{0.06} layer) was 2210 g/cm³. In addition, the LT layer of the iron-containing lithium tantalate (LT) piezoelectric single crystal thin film substrate bonded to the silicon substrate was removed, and the longitudinal wave sound velocity and attenuation of the intervening layer (SiO_{1.94}N_{0.06} layer) were determined by the Brillouin oscillation method. As a result, the longitudinal wave sound velocity of the intervening layer (SiO_{1.94}N_{0.06} layer) was 6190 m/s, and the sound attenuation rate was 1.2×10⁻³ (nm⁻¹·THz⁻²) at 55 GHz.

The transverse wave sound velocity of the SiO_{1.94}N_{0.06} layer alone, which is the intervening layer, was determined by combining the linear convergent beam ultrasonic microscope and finite element analysis, and was found to be 3750 m/s.

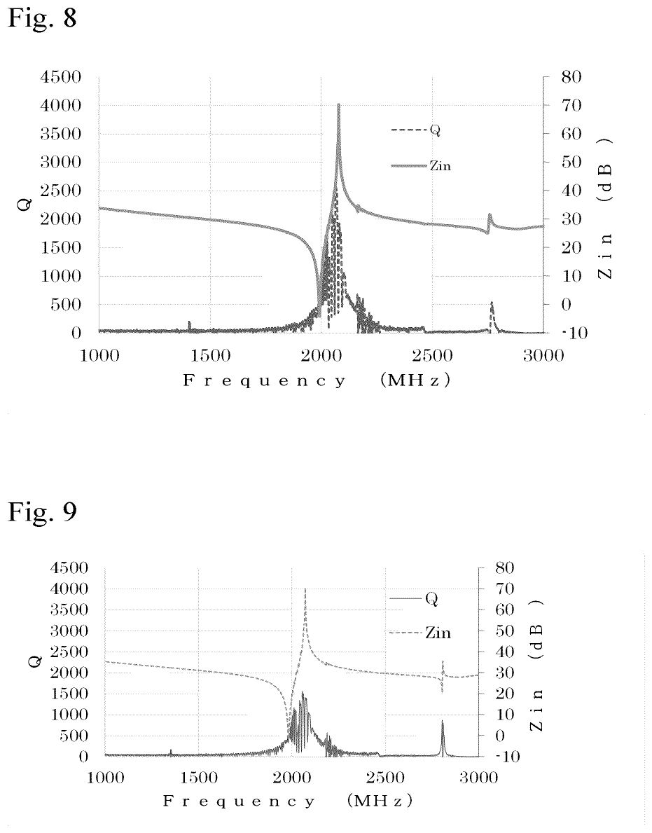

Next, the electrical characteristics of the one-port SAW resonator on the iron-containing lithium tantalate (LT) piezoelectric single crystal thin film substrate bonded to the silicon substrate created above were measured using a network analyzer. The resulting resonant waveform (input impedance (Zin) and Q value) of SAW is shown in FIG. 8. At this time, the wavelength of the surface acoustic wave was 2 μm, and the thickness of the intervening layer (SiO_{1.94}N_{0.06} layer) was 0.15 wavelengths.

Table 1 shows the resonance frequency (fr), anti-resonance frequency (fa), electromechanical coupling coefficient (k²), maximum Q value (Qmax), input impedance amplitude (ΔZ), fractional bandwidth, and spurious intensity of 2400 to 2800 MHz of the SAW resonator.

TABLE 2

| Resonance | | Electromechanical | | Amplitude of | | Maximum spurious |
|---|---|---|---|---|---|---|
| frequency | Anti-resonance | coupling coefficient | Maximum | input impedance | Fractional | intensity at |
| (fr) | frequency (fa) | (k²) | value of Q | (ΔZ) | bandwidth | 2400 to 2800 MHz |
| MHz | MHz | % | (Qmax) | (db) | % | (db) |
| 1992.9 | 2079.1 | 9.8 | 2631 | 74.5 | 4.3 | 6.7 |

Next, the iron-containing lithium tantalate (LT) piezoelectric single crystal thin film substrate bonded to the silicon substrate with the one-port SAW resonator pattern created in the same manner as in Example 1 was placed on a hot plate heated to 350° C. for 10 minutes, then placed on a cooling plate at room temperature to cool, and the electrical characteristics of the one-port SAW resonator were measured again using the network analyzer. The resulting characteristics were the same as those in Table 2. Furthermore, the 350° C. hot plate heating, cooling and measurement were repeated for a cumulative time of 4 hours in total for 350° C. hot plate heating, and the electrical characteristics of the one-port SAW resonator after each cumulative time of heating were not different from those in Table 2.

### Comparative Example 1

A polysilicon layer of 1.7 μm was formed on the surface layer of a (111) oriented high-resistance silicon substrate with a diameter of 150 nm.

Then, a melt with a composition in which the amount of lithium was reduced based on the amount of lithium contained in a lithium tantalate crystal of a congruent composition was prepared, and an iron-substituted lithium tantalate crystal was grown from the melt with the adjusted composition.

A 6-inch iron-containing 42° Y-cut lithium tantalate (LT) substrate was prepared by adding iron in an amount such that the iron content in the iron-substituted lithium tantalate crystal was 95 ppm by mass. The volume resistivity of the iron-containing 420 Y-cut lithium tantalate (LT) substrate was adjusted to 2.2×10¹⁰ Ω·cm by reduction treatment.

Then, hydrogen molecular ions were implanted into the 6-inch iron-containing lithium tantalate (LT) substrate from a surface to be bonded. The dose at this time was 9×10¹⁶ atm/cm², and the acceleration voltage was 160 KeV.

Next, a 0.4 μm thick intervening layer with a composition of SiO_{1.7} was formed by CVD method on the ion-implanted surface of the 6-inch iron-containing lithium tantalate (LT) substrate into which hydrogen molecular ions had been implanted.

Then, the silicon substrate on which the polysilicon layer was formed and the iron-containing LT substrate having the 0.4 μm thick intervening layer using SiO_{1.7} were subjected to surface activation treatment by plasma treatment. Furthermore, the silicon substrate on which the polysilicon layer was formed and the iron-containing LT substrate were bonded together with the 0.4 μm thick intervening layer using SiO_{1.7} interposed therebetween to form a bonded body.

Next, the bonded body was subjected to heat treatment at 350° C. under nitrogen to prevent the introduction of crystal defects due to misalignment of the bonding interface. Then, the heat-treated bonded body was heated to 110° C., and a wedge was driven into one end of the ion-implanted portion of the iron-containing lithium tantalate (LT) substrate to separate it into the iron-containing lithium tantalate (LT) piezoelectric single crystal thin film layer bonded to the support substrate and the remaining iron-containing lithium tantalate (LT) substrate.

The thickness of the iron-containing lithium tantalate (LT) piezoelectric single crystal thin film layer bonded to the silicon substrate after separation was measured with a spectrophotometer and found to be 0.52 μm. Next, the composite substrate consisting of the iron-containing lithium tantalate (LT) piezoelectric single crystal thin film bonded to the silicon substrate was heated at 500° C. for 6 hours.

Furthermore, the surface layer of the iron-containing lithium tantalate (LT) piezoelectric single crystal thin film of the composite substrate was polished by 20 nm, and the thickness of the iron-containing lithium tantalate (LT) piezoelectric single crystal thin film layer bonded to the silicon substrate was measured with a spectrophotometer, and found to be 0.5 μm.

The amount of Li in the intervening layer (SiO_{1.7} layer) of the composite substrate produced by the above method was measured by secondary ion mass spectrometry (SIMS), and the maximum amount of Li in the SiO_{1.7} layer was 2×10¹⁷ atom/cm³. The composition ratio of the intervening layer (SiO_{1.7} layer) was determined by X-ray photoelectron spectroscopy (XPS).

Furthermore, the density of the intervening layer (SiO_{1.7} layer) was determined by XPS (X-ray photoelectron spectroscopy) and was found to be 2240 g/cm³. The longitudinal wave sound velocity and attenuation of the intervening layer (SiO_{1.7} layer) were determined by the Brillouin oscillation method. As a result, the longitudinal wave sound velocity of the intervening layer (SiO_{1.7} layer) was 6325 m/s, and the sound attenuation rate was 10.8×10⁻² (nm⁻¹·THz⁻²) at 55 GHz.

The transverse wave sound velocity of the intervening layer (SiO_{1.7} layer) alone was determined by combining the linear convergent beam ultrasonic microscope and finite element analysis, and was found to be 3960 m/s.

Next, an Al film was sputtered to a thickness of 0.14 μm onto the surface of the composite substrate obtained above, a resist was applied, and then a resist pattern with a line width of approximately 0.5 μm was formed by i-line exposure. The Al was then etched by dry etching to form a first layer of a one-port SAW resonator.

Furthermore, a second layer of pads having an Al film thickness of 0.6 μm was formed on the composite substrate by a lift-off method. At this time, the wavelength of the surface acoustic wave was 2 μm, and the thickness of the intervening layer (SiO_{1.7} layer) was 0.2 wavelengths.

Next, the electrical characteristics of the one-port SAW resonator on the iron-containing lithium tantalate (LT) piezoelectric single crystal thin film substrate bonded to the silicon substrate created above were measured using a network analyzer. The resulting resonant waveform (input impedance (Zin) and Q value) of SAW is shown in FIG. 9.

Table 3 shows the resonance frequency (fr), anti-resonance frequency (fa), electromechanical coupling coefficient (k²), maximum Q value (Qmax), input impedance amplitude (ΔZ), fractional bandwidth, and spurious intensity of 2400 to 2800 MHz of the SAW resonator.

TABLE 3

| Resonance | | Electromechanical | | Amplitude of | | Maximum spurious |
|---|---|---|---|---|---|---|
| frequency | Anti-resonance | coupling coefficient | Maximum | input impedance | Fractional | intensity at |
| (fr) | frequency (fa) | (k²) | value of Q | (ΔZ) | bandwidth | 2400 to 2800 MHz |
| MHz | MHz | % | (Qmax) | (db) | % | (db) |
| 1983.0 | 2072.5 | 10.2 | 1556.4 | 72.2 | 4.5 | 16 |

Next, the iron-containing lithium tantalate (LT) piezoelectric single crystal thin film substrate bonded to the silicon substrate with the one-port SAW resonator pattern created above was placed on a hot plate heated to 350° C. for 10 minutes, then placed on a cooling plate at room temperature to cool, and the electrical characteristics of the one-port SAW resonator were measured again using the network analyzer. The resulting characteristics were the same as those in Table 3. Furthermore, the 350° C. hot plate heating, cooling and measurement were repeated for a cumulative time of 4 hours in total for 350° C. hot plate heating, and the electrical characteristics of the one-port SAW resonator after each cumulative time of heating were not different from those in Table 3.

### Comparative Example 2

A polysilicon layer of 1.7 μm was formed on the surface layer of a high-resistance silicon substrate with a diameter of 150 nm.

Next, an iron-free lithium tantalate crystal was grown on a lithium tantalate crystal of a congruent composition.

A 6-inch iron-free 42° Y-cut lithium tantalate (LT) substrate was prepared by processing the iron-free lithium tantalate crystal. The volume resistivity of the iron-free 42° Y-cut lithium tantalate (LT) substrate was adjusted to 2.2×¹⁰ Ω·cm by reduction treatment.

Then, hydrogen molecular ions were implanted into the 6-inch iron-free lithium tantalate (LT) substrate from a surface to be bonded. The dose at this time was 9×10¹⁶ atm/cm², and the acceleration voltage was 160 KeV.

Next, a 0.4 μm thick intervening layer with a composition of SiO₂ was formed by CVD method on the ion-implanted surface of the 6-inch iron-free lithium tantalate (LT) substrate. Then, the silicon substrate on which the polysilicon layer was formed and the iron-free LT substrate having the 0.4 μm thick intervening layer using SiO₂ were subjected to surface activation treatment by plasma treatment. Furthermore, the silicon substrate on which the polysilicon layer was formed and the iron-free LT substrate were bonded together with the 0.4 μm thick intervening layer using SiO₂ interposed therebetween to form a bonded body.

Next, the surface of the bonded body (bonded substrate) was removed by grinding and polishing.

The thickness of the iron-free lithium tantalate (LT) piezoelectric single crystal thin film layer bonded to the silicon substrate after thinning was measured with a spectrophotometer and found to be 0.5 μm.

The amount of Li in the intervening layer (SiO₂ layer) of the composite substrate produced by the above method was measured by secondary ion mass spectrometry (SIMS), and the maximum amount of Li in the SiO₂ layer was 5×10¹⁹ atom/cm³. The composition ratio of the intervening layer (SiO₂ layer) was determined by X-ray photoelectron spectroscopy (XPS).

In addition, the LT layer of the composite substrate produced by the above method was removed, and the density of the intervening layer (SiO₂ layer) was determined by X-ray reflectivity measurement (XRR). As a result, the density of the intervening layer (SiO₂ layer) was 2100 g/cm³. The LT layer of the composite substrate was removed, and the longitudinal wave sound velocity and attenuation of the intervening layer (SiO₂ layer) were determined by the Brillouin oscillation method. As a result, the longitudinal wave sound velocity of the intervening layer (SiO₂ layer) was 5400 m/s, and the sound attenuation rate was 5×10⁻¹ (nm⁻¹·THz⁻²) at 55 GHz.

The transverse wave sound velocity of the SiO₂ layer alone, which is the intervening layer, was determined by combining the linear convergent beam ultrasonic microscope and finite element analysis, and was found to be 3150 m/s.

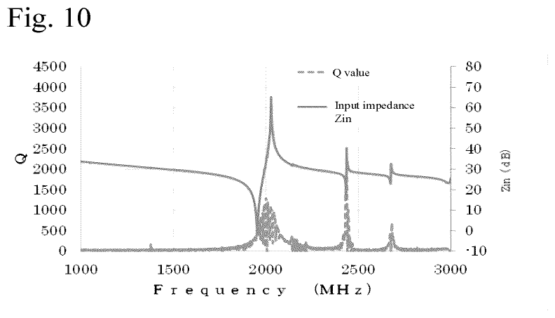

Next, the electrical characteristics of the one-port SAW resonator on the iron-free lithium tantalate (LT) piezoelectric single crystal thin film substrate bonded to the silicon substrate created above were measured using a network analyzer. The resulting resonant waveform (input impedance (Zin) and Q value) of SAW is shown in FIG. 10.

Table 4 shows the resonance frequency (fr), anti-resonance frequency (fa), electromechanical coupling coefficient (k²), maximum Q value (Qmax), input impedance amplitude (ΔZ), fractional bandwidth, and spurious intensity of 2400 to 2800 MHz of the SAW resonator. At this time, the wavelength of the surface acoustic wave was 2 μm, and the thickness of the intervening layer (SiO₂ layer) was 0.2 wavelengths.

TABLE 4

| Resonance | | Electromechanical | | Amplitude of | | Maximum spurious |
|---|---|---|---|---|---|---|
| frequency | Anti-resonance | coupling coefficient | Maximum | input impedance | Fractional | intensity at |
| (fr) | frequency (fa) | (k²) | value of Q | (ΔZ) | bandwidth | 2400 to 2800 MHz |
| MHz | MHz | % | (Qmax) | (db) | % | (db) |
| 1954.6 | 2029.2 | 8.7 | 1260 | 65 | 3.8 | 21 |

Next, the iron-free lithium tantalate (LT) piezoelectric single crystal thin film substrate bonded to the silicon substrate with the one-port SAW resonator pattern created above was placed on a hot plate heated to 350° C. for 10 minutes, then placed on a cooling plate at room temperature to cool, and the electrical characteristics of the one-port SAW resonator were measured again using the network analyzer. The resulting characteristics were the same as those in Table 4. Furthermore, the 350° C. hot plate heating, cooling and measurement were repeated for a cumulative time of 4 hours in total for 350° C. hot plate heating, and when the cumulative heating time reached about 1 hour, the electromechanical coupling coefficient (k²) began to decrease from the value in Table 3, and after the cumulative heating time reached 4 hours, the electromechanical coupling coefficient (k²) had decreased to 5%.

1. A composite substrate for surface acoustic wave devices, the composite substrate comprising:
a piezoelectric single crystal thin film;
a support substrate; and
an intervening layer provided between the piezoelectric single crystal thin film and the support substrate,
wherein the intervening layer is in contact with the piezoelectric single crystal thin film,
wherein the intervening layer has a total thickness equal to or less than twice a wavelength of the surface acoustic wave, and
wherein an attenuation of a longitudinal wave of the intervening layer, as calculated by a Brillouin oscillation method at a frequency of 40 GHz to 60 GHz, is 8×10⁻² (nm⁻¹·THz⁻²) or less.

2. The composite substrate of claim 1, wherein transverse waves of the intervening layer has a sound velocity higher than that of slow transverse waves of the piezoelectric single crystal thin film.

3. The composite substrate of claim 1, wherein the piezoelectric single crystal thin film comprises 120 ppm or less of iron, and
wherein the piezoelectric single crystal thin film has a volume resistivity of 2×10¹¹, Ω·cm or less.

4. The composite substrate of claim 1, wherein the intervening layer is either SiOₓ, in which 1.8<x<2.05, or SiO_{y}N_{z}, in which 0.02<z/(y+z)<0.1.

5. The composite substrate of claim 1, wherein the piezoelectric single crystal thin film comprises lithium tantalate or lithium niobate as a main component.

6. The composite substrate of claim 1, wherein the support substrate is silicon substrate, a sapphire substrate, an alumina substrate, a silicon carbide substrate, an aluminum nitride substrate, a silicon nitride substrate, or a quartz substrate.

7. The composite substrate of claim 1, wherein the support substrate is made of a single crystal Si and a polysilicon layer, formed on the single crystal Si.

8. The composite substrate of claim 1, wherein the intervening layer comprises Li ions in 1×10¹⁷ atom/cm³ or less.

9. The composite substrate of claim 1, wherein the intervening layer comprises SiOₓ, in which 1.8<x<2.05.

10. The composite substrate of claim 1, wherein the intervening layer comprises SiO_{y}N_{z}, in which 0.02<z/(y+z)<0.1.

11. The composite substrate of claim 1, wherein the piezoelectric single crystal thin film comprises lithium tantalate as a main component.

12. The composite substrate of claim 1, wherein the piezoelectric single crystal thin film comprises lithium niobate as a main component.

13. The composite substrate of claim 1, wherein the support substrate comprises a single crystal Si and a polysilicon layer, formed on the single crystal Si.

14. The composite substrate of claim 2, wherein the piezoelectric single crystal thin film comprises 120 ppm or less of iron, and
wherein the piezoelectric single crystal thin film has a volume resistivity of 2×10¹¹ Ω·cm or less.

15. The composite substrate of claim 2, wherein the intervening layer is either SiOₓ, in which 1.8<x<2.05, or SiO_{y}N_{z}, in which 0.02<z/(y+z)<0.1.

16. The composite substrate of claim 2, wherein the piezoelectric single crystal thin film comprises lithium tantalate or lithium niobate as a main component.

17. The composite substrate of claim 2, wherein the support substrate is silicon substrate, a sapphire substrate, an alumina substrate, a silicon carbide substrate, an aluminum nitride substrate, a silicon nitride substrate, or a quartz substrate.

18. The composite substrate of claim 2, wherein the support substrate is made of a single crystal Si and a polysilicon layer formed on the single crystal Si.
